(19) United States
(12) Patent Application Publication
(10) Pub. No.: US 2007/0049006 A1
(43) Pub. Date: Mar. 1, 2007

(54) Method for integration of a low-k pre-metal dielectric

(76) Inventors: Gregory Spencer, Pflugerville, TX (US); Paul Grudowski, Austin, TX (US)

Correspondence Address: HAMILTON & TERRILE, LLP, P.O. BOX 203518, AUSTIN, TX, 78720, US

(21) Appl. No.: 11/216,255

(22) Filed: Aug. 31, 2005

(51) Int. Cl. H01L 21/4763

(52) U.S. Cl. 438/624; 438/631; 438/637; 438/675

(57) ABSTRACT

A semiconductor manufacturing process for integrating a low-k dielectric layer in a fabrication process includes depositing a low-k dielectric layer (12) over a semiconductor structure (10) and planarizing the dielectric layer (12) with a CMP process to form a planarized low-k dielectric layer (20). By depositing a protective cap layer (30) to a substantially uniform thickness over the planarized dielectric layer (20) before etching a contact hole (40), the planarized dielectric layer (20) is protected from damage from the contact hole formation processes (e.g., contact photolithography, etch and/or ash). The contact hole (40) is then filled with a metal (50), and any excess metal is removed with a CMP process to form the contact plugs (60), where the CMP process is also used to thin the protective cap layer (62, 64) or remove it entirely.

### BACKGROUND OF THE INVENTION

1. Field of the Invention

The present invention is directed in general to the field of semiconductor devices. In one aspect, the present invention relates to the formation a low-k dielectric layer.

2. Description of the Related Art

Semiconductor devices typically include device components (such as transistors and capacitors) that are formed on or in a substrate as part of the front end of line (FEOL) processing. In addition, interconnect features (such as contacts, metal lines and vias) that connect the device components to the outside world are included as part of the back end of line (BEOL) integration process whereby one or more dielectric layers are formed in and between the interconnect features for purposes of electrically isolating the interconnect features and device components. For example, the beginning of the BEOL process typically forms a dielectric layer between the device components on the substrate and the first layer of metal in the interconnect level. This dielectric layer between the device level and the interconnect level is known as the pre-metal dielectric.

Until recently, oxide dielectric layers were typically used for the pre-metal dielectric layer. Such oxide dielectric layers have a standard permittivity or dielectric constant, and provide adequate electrical isolation between interconnect features and the underlying device components. In addition, oxide dielectric layers were able to withstand the etch processes required to form contact openings for the contacts. But as geometries in semiconductors continue to shrink in size, the RC delay and crosstalk effects caused by the more densely packed interconnect features have increased. In response, low dielectric constant (low-k) dielectric layers are increasingly used to isolate the interconnect and metallization features from the underlying device components in order to minimize RC delay and crosstalk. As will be appreciated, a low-k material is a material having a relative permittivity or dielectric constant that is typically less than four.

Accordingly, a need exists for an improved process for fabricating a pre-metal dielectric layer that will provide adequate isolation between interconnect features and the underlying device components. In addition, there is a need for a pre-metal dielectric layer that can be effectively and reliably integrated into the back end of line process. There is also a need for an improved pre-metal dielectric layer that will improve transistor and first metal performance. There is also a need for an improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a partial cross-sectional view of a semiconductor device wherein a low-k dielectric pre-metal layer has been deposited over the device components formed on a substrate;

FIG. 2 illustrates processing subsequent to FIG. 1 after the low-k dielectric pre-metal layer has been planarized;

FIG. 3 illustrates processing subsequent to FIG. 2 after a protective cap layer has been deposited;

FIG. 4 illustrates processing subsequent to FIG. 3 after a contact hole has been etched through the protective cap layer and the low-k dielectric pre-metal layer;

FIG. 5 illustrates processing subsequent to FIG. 4 after a contact metal material is formed to fill the contact hole; and

FIG. 6 illustrates processing subsequent to FIG. 5 after removal of the excess metal and at least part of the protective cap layer with a chemical mechanical polish step.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

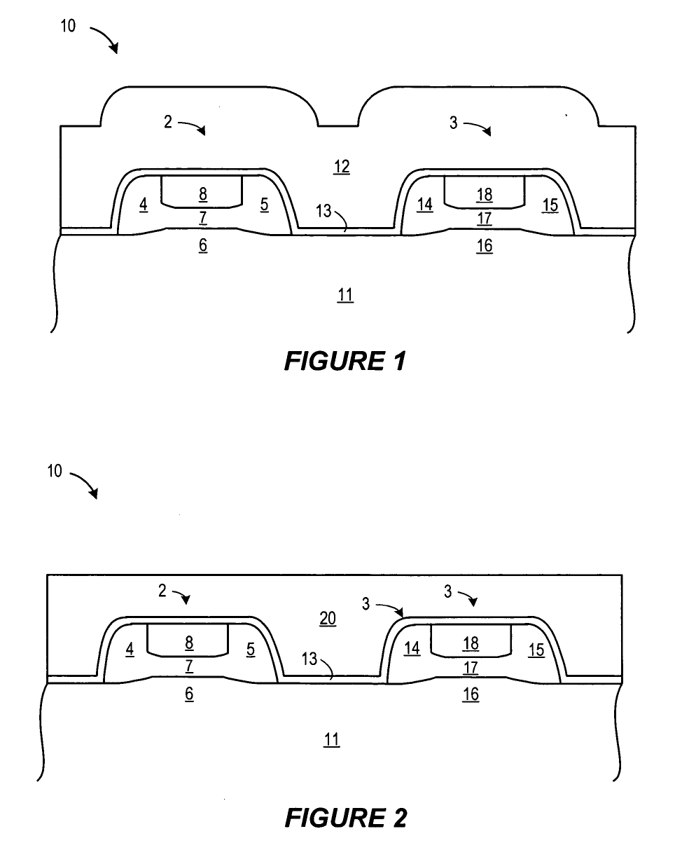

A method and apparatus are described for integrating a low-k pre-metal dielectric layer in formation of the contact metal by forming a protective cap layer after planarizing the deposited low-k pre-metal dielectric layer and before etching the contact hole so as to protect the low-k pre-metal dielectric layer from the contact hole etch processing. The disclosed techniques may be used to fabricate a low-k dielectric layer at any damascene or non-planar level. Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified drawings in order to avoid limiting or obscuring the present invention. Such descriptions and representations are used by those skilled in the art to describe and convey the substance of their work to others skilled in the art. Various illustrative embodiments of the present invention will now be described in detail with reference to FIGS. 1-6. It is noted that, throughout this detailed description, certain layers of materials will be deposited and removed to form the depicted semiconductor structures. Where the specific procedures for depositing or removing such layers are not detailed below, conventional techniques to one skilled in the art for depositing, removing or otherwise forming such layers at appropriate thicknesses shall be intended. Such details are well known and not considered necessary to teach one skilled in the art of how to make or use the present invention.

FIG. 1 is a partial cross-sectional view of a semiconductor device 10 wherein a low-k dielectric pre-metal layer 12 has been deposited over the device components 2, 3 formed on a substrate 11. As will be appreciated, the device components may be a MOSFET transistor, double gate fully depleted semiconductor-on-insulator (FDSOI) transistor, NVM transistor, capacitor, diode or any other integrated circuit component formed on the substrate 11. Depending on the type of transistor device being fabricated, the substrate 11 may be implemented as a bulk silicon substrate, single crystalline silicon (doped or undoped), or any semiconductor material including, for example, Si, SiC, SiGe, SiGeC, Ge, GaAs, InAs, InP as well as other Group III-IV compound semiconductors or any combination thereof, and may optionally be formed as the bulk handling wafer. In addition, the substrate 11 may be implemented as the top semiconductor layer of a semiconductor on-insulator (SOI) structure or a hybrid substrate comprised of bulk and/or SOI regions with differing crystal orientation.

In the simplified device example illustrated in FIG. 1, a first device component 2 is a MOSFET transistor which is formed in part from a gate electrode layer 8 that is formed over and insulated from a channel region 6 in the substrate 11 by a gate dielectric 7. In forming MOSFET transistor 2, a gate dielectric layer 7 is formed by depositing or growing a dielectric (e.g., silicon dioxide, oxynitride, metal-oxide, nitride, etc.) over the semiconductor substrate 11 using chemical vapor deposition (CVD), plasma-enhanced chemical vapor deposition (PECVD), physical vapor deposition (PVD), atomic layer deposition (ALD), thermal oxidation, or any combination thereof. The gate electrode layer 8 may be formed from any conductive material (e.g., polysilicon, metal, or the like) that is blanket deposited over the gate dielectric layer 7 by CVD, PECVD, PVD, ALD, or any combination thereof. One or more sidewall spacers 4, 5 are shown as being formed on the side of the gate electrode layer 8, and are typically used in the formation of source and drain regions (not shown) and self-aligned silicide (not shown) in the substrate 11. The second device component 3 may also be a MOSFET transistor, or may be another component, such as a non-volatile memory (NVM) device having a channel region 16 over which is formed a first insulating layer or tunnel dielectric 17 and an NVM gate stack, which is depicted as a single structure 18 which includes a floating gate, a control dielectric layer formed over the floating gate, and a control gate formed over the control dielectric layer (not separately shown). In addition, one or more sidewall spacers 14, 15 shown as being formed on the side of the NVM gate stack 18 are typically used in the formation of source and drain regions (not shown) in the substrate 11. In forming the NVM device 3, a tunnel dielectric layer 17 is formed by depositing or growing a dielectric (e.g., silicon dioxide, oxynitride, metal-oxide, nitride, etc.) over the semiconductor substrate 11 using CVD, PECVD, PVD, ALD, thermal growth or any combination thereof. In the NVM gate stack 18, a floating gate layer (not separately shown) acts as a charge storage layer that is charged under control of the control gate and control dielectric (not separately shown). As will be appreciated, there are other types of NVM devices besides floating gate devices, including nanocluster devices and SONOS (silicon-oxide-nitride-oxide-silicon) devices.

Regardless of the specific type of device components 2, 3 formed on the substrate 11, the components are electrically isolated with a BEOL process that begins by blanket depositing a conformal or near conformal etch stop layer 13 and a layer of low-k dielectric pre-metal material 12 over the device components 2, 3 by CVD, PECVD, PVD, ALD, or any combination thereof to a thickness of approximately 400-1000 nanometers, though other thicknesses may also be used. By depositing the low-k dielectric pre-metal layer 12 over the device components 2, 3 such that the low-k dielectric completely covers the top and sides of the device components 2, 3, a non-planar upper surface is obtained, regardless of whether layer 12 is planarizing or conformal in nature. This non-planarity is due in part to variation in device component density and topography of the devices.

As will be appreciated, the low-k dielectric pre-metal layer 12 may be formed from one or more constituent layers. In an illustrative embodiment, a layer of low-k dielectric material, such as black diamond and other organic or inorganic low-k dielectric material, is deposited over the semiconductor structure 10. In another embodiment, one or more cold chuck (0° C.) CVD films may be deposited using hydrogen peroxide (H₂0₂) and a silicon-containing precursor. In accordance with an illustrative embodiment, the low-k dielectric pre-metal layer 12 is a single-layer cold chuck CVD film of low-k (k˜3.0) carbon-doped oxide film that is deposited using methylsilane (CH₃—SiH₃) as the silicon precursor with H₂0₂ to a thickness of 800 nm. After deposition, the carbon-doped oxide film is cured using an in-situ plasma cure process. Of course, other component layer materials and/or processes may be used to form the low-k dielectric pre-metal layer 12.

After the low-k dielectric pre-metal layer 12 has been formed over the semiconductor device 10, the layer 12 is polished into a planarized dielectric layer 20, as illustrated in FIG. 2. In particular, a chemical mechanical polishing step may be used to polish the deposited low-k dielectric pre-metal layer 12, though other etch processes may be used to planarize the dielectric layer 12.

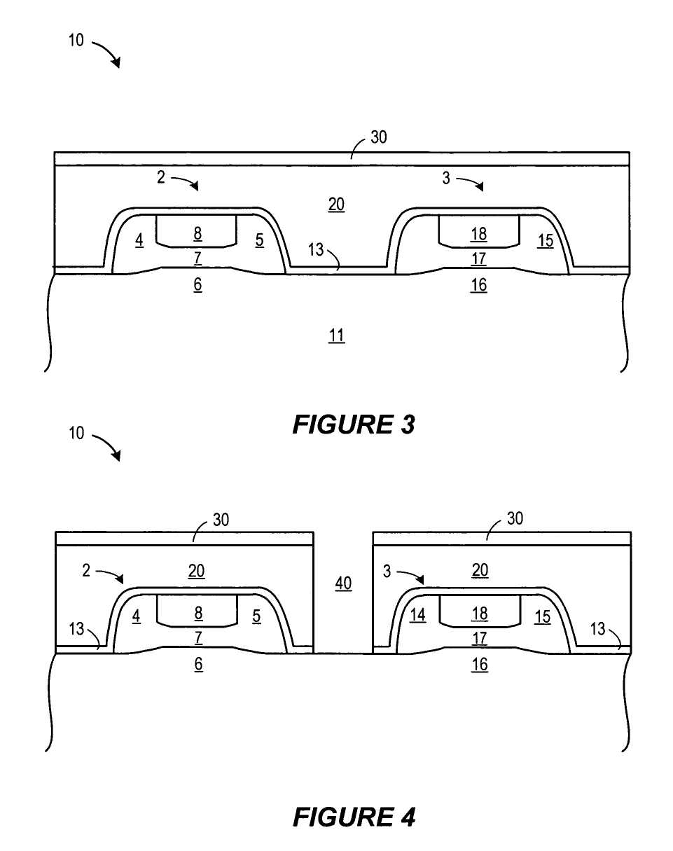

FIG. 3 illustrates processing of the semiconductor device 10 subsequent to FIG. 2 after a protective cap layer 30 has been deposited or otherwise formed on the planarized dielectric layer 20 to a substantially uniform thickness of approximately 50 nanometers, though other thicknesses may also be used. Any desired material may be used to form the protective cap layer 30, so long as the material protects the underlying planarized dielectric layer 20 from etch and/or ash damage when the contact holes are opened. In accordance with various embodiments, the protective cap layer 30 may be formed from a PECVD TEOS oxide layer or a deposited layer of silicon carbonitride (SiCN).

FIG. 4 illustrates processing of the semiconductor device 10 subsequent to FIG. 3 after a contact hole 40 has been etched through the protective cap layer 30 and the planarized low-k dielectric pre-metal layer 20 and the etch stop layer 13 to form an opening above a selected contact region over the source/drain region in the substrate, though the contact region may also be located over the gate (e.g., gate electrode 8). Any desired contact etch process may be used to form the contact hole 40, such as a three stage etch process which removes selected portions of the protective cap layer 30 and the planarized low-k dielectric layer 20, and then opens the etch stop layer 13 over a selected contact region. As a preliminary step, a layer of photoresist (not shown) may be applied and patterned directly on the protective cap layer 30, though multi-layer masking techniques may also be used to define the location of the contact hole 40. The exposed portions of the protective cap layer 30, the planarized low-k dielectric pre-metal layer 20, and the etch stop layer 13 are then removed by using the appropriate etchant processes to etch a contact hole 40 such as a reactive ion etching (RIE) process using 0₂, N₂, or a fluorine-containing gas. For example, an etch process that is selective to the protective cap layer 30 (such as an Argon, C₄F₈ chemistry that is used to etch TEOS) is used to etch through the exposed portion of the protective cap layer 30, while an etch process that is selective for the material of the low-k dielectric layer 20 and to the etch stop layer 13 (such as an Argon, CHF₃, or CF₄ chemistry that is used to etch carbon-doped oxide film) is used to etch through the exposed portion of the low-k dielectric layer 20 while stopping on etch stop layer 13, and a further etch step to open the etch stop layer 13 (such as an Argon CF₄ chemistry). In addition, an ash process may be included as part of the contact hole formation process to remove the photoresist layer.

As will be appreciated, there are number of damaging mechanisms in the contact hole formation process that can damage an unprotected low-k dielectric material, depending on the type of etch or ash process used. For example, in the RIE process, CxFyHz-based gas chemistries react with the Si—CH₃ bonds in the porous low-k dielectric material to form CFx and some silicon-containing volatile byproducts. In a subsequent ashing process (which may be an O₂-based photoresist strip process), the CFx compounds decompose into volatile species, such as CO and CO₂. As the O₂ concentration in the photoresist strip chemistry is increased, the CFx polymer is removed more efficiently. This causes carbon depletion from the low-k dielectric material which leaves behind several dangling silicon bonds. When these species come into contact with the moisture in the ambient, Si—OH bonds are formed. This change in composition of the dielectric material leads to an increase in dielectric constant of the material, often on the order of 0.5 or higher. Accordingly, the contact hole formation process should be optimized to reduce the level of oxidation so that damage to the unprotected sidewall of the low-k dielectric layer 20 in the contact hole 40 is minimized.

In addition, various embodiments of the present invention protect the planarized low-k dielectric layer 20 from such etch/ash damage by providing the protective cap layer 30 over the previously-planarized dielectric layer. The protective cap layer 30 acts to prevent oxidation at the upper surface of the planarized low-k dielectric layer 20. In addition, by depositing the protective cap layer 30 after planarizing the dielectric layer 20 and before the contact hole is formed, a substantially uniform thickness is obtained for the protective cap layer 30 over the entirety of the semiconductor device 10. Such uniformity of thickness may prevent spatial dependencies in the protection against etch/ash damage that can result from protective cap layers that are not uniformly thick, such as can occur when a protective cap layer is deposited prior to planarization of the deposited dielectric layer. In addition, lack of uniformity in protective cap layer 30 will create spatial dependencies in the effective dielectric constant of the material directly under the first metal layer. Therefore, this non-uniformity of the protective cap layer 30 will lead to spatially dependent first metal layer RC characteristics.

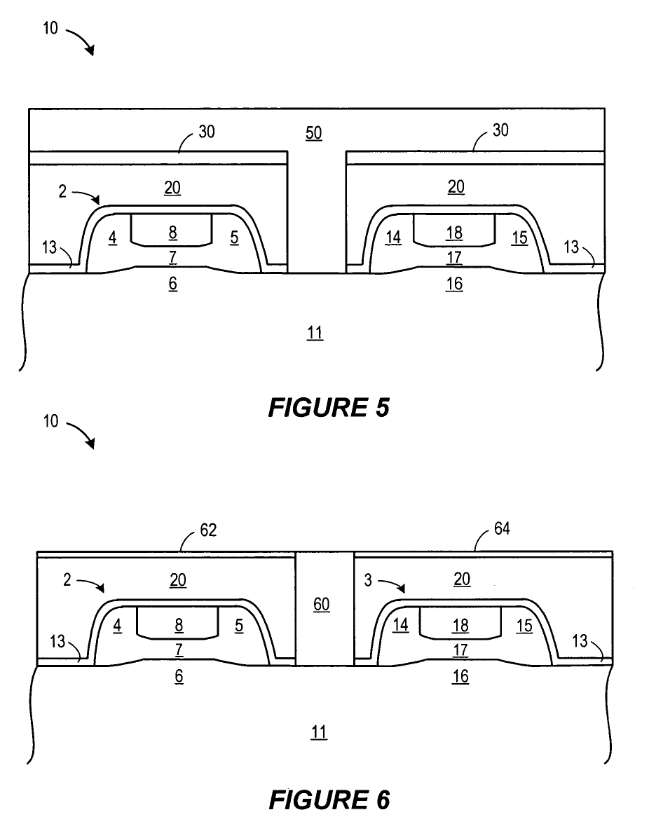

FIG. 5 illustrates processing of the semiconductor device 10 subsequent to FIG. 4 after a layer of contact metal material 50 is formed to fill the contact hole 40. As illustrated, one or more conductive materials or layers 50 (such as tungsten, copper and/or a barrier layer) are deposited to fill the contact hole 40 to form a contact plug 60 (described below). This may be accomplished using any desired technique to fill the contact holes, such as depositing one or more layers of contact metal, such as tungsten.

FIG. 6 illustrates processing of the semiconductor device 10 subsequent to FIG. 5 after a chemical mechanical polish step is used to remove the excess conductive material from the contact metal layer 50 up to and/or including at least part of the protective cap layer 30, thereby forming a contact plug 60. In a selected embodiment, a chemical mechanical polish (CMP) process is used to polish the contact metal layer 50 until it is etched back and substantially co-planar with the protective cap layer 30. By using a timed CMP process, the excess metal is removed, leaving only the metal plugs 60 in the contact hole 40.

While the CMP polish may be timed to stop at the protective cap layer 30, additional polishing may also be used to remove all or part of the protective cap layer 30. For example, when the protective cap layer 30 is formed from a standard-k dielectric material (such as TEOS or SiCN), the CMP process may be used to thin the protective cap layer (62, 64). In addition or in the alternative, the CMP process may be used to overpolish the protective cap layer 30 so as to remove it entirely. With either approach (thinning or removal), the overall k_{eff} of the stack will be reduced.

As will be appreciated, additional processing steps may be used to complete the fabrication of the device components 2, 3 into functioning circuit elements. As examples, one or more sacrificial oxide formation, stripping, isolation region formation, gate electrode formation, extension implant, halo implant, spacer formation, source/drain implant, annealing, silicide formation, and polishing steps may be performed, along with conventional backend processing (not depicted), typically including formation of multiple levels of interconnect(s) that are used to connect the device components in a desired manner to achieve the desired functionality. Thus, the specific sequence of steps used to complete the fabrication of the device components may vary, depending on the process and/or design requirements. Also, other semiconductor device levels may be formed underneath or above semiconductor device 10.

In one form, a method of fabricating a low-k pre-metal dielectric is provided whereby a low-k pre-metal dielectric layer is deposited over a semiconductor structure and planarized with a CMP process. Next, a protective cap layer is deposited to a uniform thickness over the planarized dielectric layer before etching a contact hole by performing any desired contact photolithography, etch and/or ash processes. The contact hole is then filled with a metal, and any excess metal is removed with a CMP process which may also be used to thin or remove the protective cap layer.

In another form, a method is described for manufacturing a semiconductor device on which one or more device components are formed. After forming the device components and blanket depositing an optional etch stop layer, the device components are covered by depositing low-k pre-metal dielectric layer. The low-k pre-metal dielectric layer is then polished into a planarized dielectric layer, and a protective cap layer is deposited over the planarized dielectric layer, such as by depositing a layer of TEOS oxide or silicon carbonitride. Contact holes are opened by using contact photolithography, etch and ash steps to remove the protective cap layer and low-k pre-metal dielectric layer over selected contact regions in the substrate or on a semiconductor device component. After filling the contact holes with a conductive material, the excess conductive material is removed with a final CMP process to leave a conductive material plug in the contact holes. The final CMP process may also be used to remove all or some of the protective cap layer from above the planarized dielectric layer.

In yet another form, a method is described for forming and etching a low-k dielectric layer with reduced damage to the low-k dielectric. According to the disclosed method, a low-k dielectric layer is formed over a semiconductor structure and is then polished with a chemical mechanical polishing process to planarize an upper surface of the low-k dielectric layer. Next, a protective barrier layer is deposited over the upper surface of the low-k dielectric layer, and an opening is selectively etched in the protective barrier layer and the low-k dielectric layer. The selective etching process leaves an unetched portion of the protective barrier layer on the upper surface of the low-k dielectric layer to protect the low-k dielectric layer from etch damage. For example, the unetched portion of the protective barrier layer will protect the upper surface of the low-k dielectric layer from any ash damage in the selective etching process. While the method may be used to form any low-k dielectric layer, a selected embodiment uses the method to form a low-k dielectric pre-metal layer over one or more device components in a semiconductor structure, in which case a layer of conductive material is deposited to fill the opening, and a second chemical mechanical polishing process is performed to remove excess conductive material from outside the opening. The second chemical mechanical polishing process may be used to remove not only the excess conductive material, but also at least part of the protective barrier layer.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the methodology of the present invention may be applied in areas other than pre-metal dielectric layers, and may be applied to protect any non-planar low-k dielectric layer that from damage caused by etch or ash processing. In addition, the invention is not limited to any particular type of integrated circuit described herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method of forming a semiconductor structure with a dielectric layer, comprising:
providing a semiconductor structure;
depositing a low-k dielectric layer over the semiconductor structure;
planarizing the low-k dielectric layer to form a planarized low-k dielectric layer;
depositing a protective cap layer over the planarized low-k dielectric layer;
opening a contact hole through a predetermined portion of the protective cap layer and planarized low-k dielectric layer;
filling the contact hole with a conductive material;
removing any excess conductive material from outside the contact hole by polishing the semiconductor structure down to at least the protective cap layer.

2. The method of claim 1, wherein polishing the semiconductor structure down to at least the protective cap layer comprises using a chemical mechanical polish process to remove all of the protective cap layer.

3. The method of claim 1, wherein polishing the semiconductor structure down to at least the protective cap layer comprises using a chemical mechanical polish process to remove part of the protective cap layer.

4. The method of claim 1, wherein planarizing the low-k dielectric layer comprises using a chemical mechanical polish process to planarize the low-k dielectric layer.

5. The method of claim 1, wherein depositing a low-k dielectric layer comprises forming a stack of a plurality of low-k dielectric layers.

6. The method of claim 1, wherein the protective cap layer comprises a deposited layer of silicon carbonitride.

7. The method of claim 1, wherein the protective cap layer comprises a layer of deposited tetraethylorthosilicate (TEOS).

8. The method of claim 1, wherein opening a contact hole comprises performing contact photolithography and etch processes.

9. The method of claim 1, wherein opening a contact hole comprises performing contact photolithography, etch and ash processes

10. A method of manufacturing a semiconductor device, comprising:
(a) forming one or more semiconductor device components on a substrate;
(b) depositing a low-k dielectric layer over the semiconductor device components;
(c) polishing the low-k dielectric layer into a planarized dielectric layer;
(d) depositing a protective cap layer over the planarized dielectric layer;
(e) opening at least one contact hole over a selected contact region;
(f) filling the contact hole with a conductive material; and
(g) removing excess conductive material with a chemical mechanical polish process to leave a conductive material plug in the contact hole.

11. The method of claim 10, where the chemical mechanical polish process removes only some of the protective cap layer from above the planarized dielectric layer.

12. The method of claim 10, where the chemical mechanical polish process removes all of the protective cap layer from above the planarized dielectric layer.

13. The method of claim 10, where opening at least one contact hole comprises performing contact photolithography, etch and ash steps.

14. The method of claim 10, further comprising blanket depositing an etch stop layer over the semiconductor device components and substrate before depositing a low-k dielectric layer over the semiconductor device components.

15. The method of claim 10, where the protective cap layer comprises a deposited layer of TEOS oxide or a deposited layer of silicon carbonitride (SiCN).

16. A method of forming and etching a low-k dielectric layer, comprising:
forming a low-k dielectric layer over a semiconductor structure; then
performing a first chemical mechanical polishing process to planarize an upper surface of the low-k dielectric layer; then
depositing a protective barrier layer over the upper surface of the low-k dielectric layer; and then
selectively etching an opening in the protective barrier layer and the low-k dielectric layer such that an unetched portion of the protective barrier layer is left on the upper surface of the low-k dielectric layer to protect the low-k dielectric layer from etch damage.

17. The method of claim 16, wherein the unetched portion of the protective barrier layer protects the upper surface of the low-k dielectric layer from any ash damage in the selective etching process.

18. The method of claim 16, where the low-k dielectric layer comprises a low-k dielectric pre-metal layer that is formed over one or more device components in a semiconductor structure.

19. The method of claim 16, further comprising:
depositing a layer of conductive material to fill the opening, and
performing a second chemical mechanical polishing process to remove excess conductive material from outside the opening.

20. The method of claim 19, wherein the second chemical mechanical polishing process removes at least part of the protective barrier layer.
